(19) United States
(12) Patent Application Publication
(10) Pub. No.: US 2008/0173924 A1
(43) Pub. Date: Jul. 24, 2008

(54) SEMICONDUCTOR DEVICE AND METHOD FOR MANUFACTURING SEMICONDUCTOR DEVICE

(75) Inventors: Tomonori TABE, Anpachi-gun (JP); Satoru Shimada, Hashima-shi (JP); Kazunori Fujita, Yoro-gun (JP); Yoshikazu Yamaoka, Ogaki-shi (JP)

Correspondence Address: DITTHAVONG MORI & STEINER, P.C., 918 Prince St., Alexandria, VA, 22314, US

(73) Assignee: SANYO ELECTRIC CO., LTD., Moriguchi-shi (JP)

(21) Appl. No.: 11/830,369

(22) Filed: Jul. 30, 2007

(30) Foreign Application Priority Data
Jul. 31, 2006 (JP) 2006-208537
Jun. 12, 2007 (JP) 2007-155471

(51) Int. Cl. H01L 27/088; H01L 21/283

(52) U.S. Cl. 257/315; 438/586; 257/E27.06; 257/E29.119; 257/E29.121; 257/E21.159; 257/E21.179

(57) ABSTRACT

A semiconductor device that reduces the interval between gate electrodes. The semiconductor device includes a semiconductor substrate, a plurality of gate electrodes buried in the semiconductor substrate, a plurality of first insulation layers arranged respectively on the plurality of gate electrodes, a conductive layer formed on the surface of the semiconductor substrate near the plurality of gate electrodes and the plurality of first insulation layers, and a conductor layer arranged on at least the conductive layer.

### CROSS-REFERENCE TO RELATED APPLICATIONS

This application is based upon and claims the benefit of priority from the prior Japanese Patent Applications No. 2006-208537, filed on Jul. 31, 2006, and No. 2007-155471, filed on Jun. 12, 2007, the entire contents of which are incorporated herein by reference.

### BACKGROUND OF THE INVENTION

The present invention relates to a semiconductor device and a method for manufacturing a semiconductor device.

Electronic devices such as portable devices and home appliances use techniques developed for integrating a control circuit and a plurality of power transistors (semiconductor elements) on a single semiconductor substrate.

FIG. 1 is a schematic cross-sectional view showing the structure of a conventional vertical metal oxide semiconductor (MOS) transistor described in Japanese Laid-Open Patent Publication No. 2003-303960.

An epitaxial layer 33 is formed on a monocrystalline silicon substrate 32. A buried layer 38 is formed between the substrate 32 and the epitaxial layer 33 so as to extend along the interface between the substrate 32 and the epitaxial layer 33. A portion of the epitaxial layer 33 on the buried layer 38 is used as a formation region for gate electrodes 48 and a source region 45. The epitaxial layer 33 includes a channel layer 44 and the source region 45 that are formed through dual diffusion.

The epitaxial layer 33 includes a plurality of trenches 46 in which the gate electrodes 48 are formed. The trenches 46 extend downward from the surface of the epitaxial layer 33 and are arranged at regular intervals. The trenches 46 are formed to be deep enough to extend through the source region 45 and the channel layer 44 but not deep enough to extend to the buried layer 38. A gate insulation film 47 is formed to substantially cover the entire inner surface of each trench 46. The gate electrode 48 is filled in each trench 46 to cover the gate insulation film 47. The gate electrodes 48 are formed from polycrystalline silicon. The gate insulation films 47 are formed from silicon oxidation films.

The epitaxial layer 33 further includes trenches 39 that are deep enough to reach the buried layer 38. A silicon oxidation film 40 covers the inner surface of each trench 39. A lead layer 41, which is formed from polycrystalline silicon, is buried in each trench 39.

An insulation layer 49 is formed on the epitaxial layer 33. Contact holes 49a and 49b are formed in the insulation layer 49. A source electrode 51 is formed in the contact hole 49a. A drain electrode 50 is formed in the contact hole 49b. The-drain electrode 50 is connected to the lead layer 41. The source electrode 51 is connected to the source region 45. The gate electrode 48 formed in each trench 46 is insulated from the source electrode 51 by the gate insulation film 47 and the insulation layer 49. The source electrode 51 is formed to cover a plurality of gate electrodes 48 (three in the drawing).

To drive a large load, such a semiconductor device includes transistors of which the total gate length is as long as several millimeters. In this structure, the gate region occupies a large area of the semiconductor substrate. To reduce the size of such a semiconductor device, the gate electrodes 48 must be arranged at finer intervals.

When the gate electrodes 48 are arranged at finer intervals, the area of the source region 45 decreases accordingly. As a result, the diameter of the contact holes 49a connected to the source region 45 must to be reduced. The contact holes 49a are required to have at least a predetermined area to enable the flow of the desired current through the source region 45. Thus, the diameter of the contact holes 49a cannot be reduced to a value that is less than a predetermined value.

Further, when the contact holes 49a are misaligned with respect to the source region 45 between the gate electrodes 48, the source electrode 51 may be disconnected from the source region 45. Further, short-circuiting may occur between the source electrode 51 and the gate electrodes 48. To prevent such problems, the region of the source electrode 51 (the interval between the gate electrodes 48) must be larger than the diameter of the contact holes 49a by an amount corresponding to an extension region. Thus, there is a limit to the reduction of the interval between gate electrodes with the conventional transistor structure.

### SUMMARY OF THE INVENTION

The present invention provides a semiconductor device and a method for manufacturing a semiconductor device that enables reduction of the interval between gate electrodes.

One aspect of the present invention provides a semiconductor device including a semiconductor substrate having a surface. A plurality of gate electrodes are buried in the semiconductor substrate. A plurality of first insulation layers are respectively arranged on the plurality of gate electrodes. A conductive layer is formed on the surface of the semiconductor substrate near the plurality of gate electrodes and the plurality of first insulation layers. A conductor layer is arranged on at least the conductive layer.

A further aspect of the present invention is a method for manufacturing a semiconductor device. The method includes preparing a semiconductor substrate having a surface, burying a plurality of gate electrodes in the semiconductor substrate, arranging a plurality of first insulation layers respectively on the plurality of gate electrodes, forming a conductive layer on the surface of the semiconductor substrate near the plurality of gate electrodes and the plurality of first insulation layers, and arranging a conductor layer on at least the conductive layer.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a schematic cross-sectional view showing the structure of a conventional vertical MOS transistor;

FIG. 2 is a schematic cross-sectional view of a semiconductor device according to a first embodiment of the present invention taken along line X-X in FIG. 3;

FIG. 3 is a schematic plan view of the semiconductor device of FIG. 2;

FIG. 4 is a schematic cross-sectional view showing a manufacturing process for the semiconductor device of FIG. 2;

FIG. 5 is a schematic cross-sectional view showing a manufacturing process for the semiconductor device of FIG. 2;

FIG. 6 is a schematic cross-sectional view showing a manufacturing process for the semiconductor device of FIG. 2;

FIG. 7 is a schematic cross-sectional view showing a manufacturing process for the semiconductor device of FIG. 2;

FIG. 8 is a schematic cross-sectional view showing a manufacturing process for the semiconductor device of FIG. 2;

FIG. 9 is a schematic cross-sectional view showing a manufacturing process for the semiconductor device of FIG. 2;

FIG. 10 is a schematic cross-sectional view showing a manufacturing process for the semiconductor device of FIG. 2;

FIG. 11 is a schematic cross-sectional view showing a manufacturing process for the semiconductor device of FIG. 2;

FIG. 12 is a schematic cross-sectional view showing a manufacturing process for the semiconductor device of FIG. 2;

FIG. 13 is a schematic cross-sectional view showing a manufacturing process for the semiconductor device of FIG. 2;

FIG. 14 is a schematic cross-sectional view showing a manufacturing process for the semiconductor device of FIG. 2;

FIG. 15 is a schematic cross-sectional view showing a manufacturing process for the semiconductor device of FIG. 2;

FIG. 16 is a schematic cross-sectional view showing a manufacturing process for the semiconductor device of FIG. 2;

FIG. 17A is a schematic cross-sectional view showing a manufacturing process for the semiconductor device of FIG. 2;

FIG. 17B is a cross-sectional view taken along line 17B-17B of FIG. 17A;

FIG. 18 is a schematic cross-sectional view showing a manufacturing process for the semiconductor device of FIG. 2;

FIG. 19 is a schematic cross-sectional view showing a manufacturing process for the semiconductor device of FIG. 2;

FIG. 20 is a schematic cross-sectional view showing a manufacturing process for the semiconductor device of FIG. 2;

FIG. 21 is a schematic cross-sectional view showing a manufacturing process for the semiconductor device of FIG. 2; and

FIG. 22 is a schematic cross-sectional view of a semiconductor device according to a second embodiment of the present invention.

### DETAILED DESCRIPTION OF THE PREFERRED EMBODIMENTS

In the drawings, like numerals are used for like elements throughout.

A semiconductor device according to a first embodiment of the present invention will now be described with reference to the drawings.

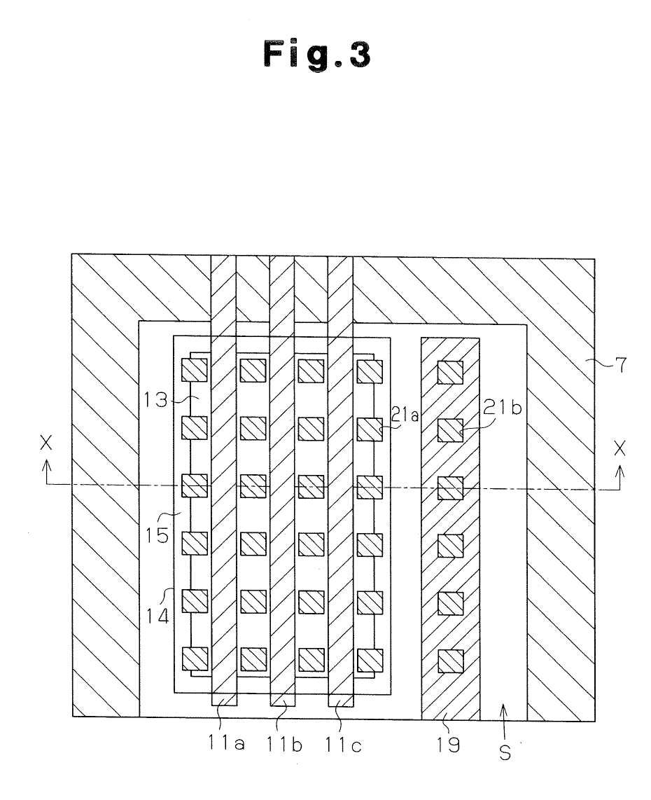

FIG. 2 is a schematic cross-sectional view showing the semiconductor device of the first embodiment. FIG. 3 is a schematic plan view of the semiconductor device. FIG. 2 is a cross-sectional view of the semiconductor device taken along line X-X in FIG. 3.

The semiconductor device of the first embodiment has a vertical MOS transistor structure as shown in FIG. 2. An n-type buried diffusion layer 3 is formed on a p-type monocrystalline silicon substrate 1. An n-type epitaxial silicon layer 5 is formed on the buried diffusion layer 3. The epitaxial silicon layer 5 is divided into different regions by an isolation diffusion layer 4, which surrounds the buried diffusion layer 3, and an isolation diffusion layer 6. In the first embodiment, the silicon substrate 1 and the epitaxial silicon layer 5 form a semiconductor substrate in the present invention.

The epitaxial silicon layer 5 includes trenches 17 formed to extend from the surface of the epitaxial silicon layer 5 to the buried diffusion layer 3. A silicon oxidation film 18, which serves as a spacer, covers the inner surface of each trench 17. The silicon oxidation film 18 functions to prevent diffusion of impurities contained in polysilicon from other regions and maintain the withstand voltage with the surrounding epitaxial silicon layer 5. A lead layer 19 is filled in each trench 17. The lead layer 19 is formed from polysilicon containing a large amount of n-type impurity, such as phosphorous (P). Accordingly, each lead layer 19 is formed as a high concentration n-type region. Referring to FIG. 3, the lead layers 19 are formed at predetermined positions in a formation region S defined by the isolation layer 7 in a manner that a predetermined number of gate electrodes are associated with each lead layer 19. For example, local oxidation of silicon (LOCOS) is performed to form the isolation layer 7. In the first embodiment, three gate electrodes 11a to 11c are provided for each lead layer 19.

Referring to FIG. 2, the epitaxial silicon layer 5 includes an n-type source diffusion layer 13 and a p-type body diffusion layer (channel layer) 14 that are formed through dual diffusion. The epitaxial silicon layer 5 includes trenches 9a to 9c extending downward from the surface of the epitaxial silicon layer 5. The trenches 9a to 9c are formed to be deep enough to extend through the source diffusion layer 13 and the body diffusion layer 14 but not deep enough to extend to the buried diffusion layer 3. Gate insulation films 10a to 10c substantially cover the entire inner surfaces of the trenches 9a to 9c, respectively. Gate electrodes 11a to 11c are filled in the trenches 9a to 9c to cover the gate insulation films 10a to 10c. The gate electrodes 11a to 11c are formed from polysilicon containing a large amount of n-type impurity, such as phosphorous. The gate insulation films 10a to 10c are formed by silicon oxidation films. Silicon oxidation films 12a to 12c are formed on the gate electrodes 11a to 11c by oxidizing portions of the gate electrodes 11a to 11c (polysilicon) in a self-aligned manner. The upper surfaces of the silicon oxidation films 12a to 12c are substantially with the upper surface of the source diffusion layer 13. Referring to FIG. 3, the gate electrodes 11a to 11c are arranged in parallel to one another and divide the source diffusion layer 13 into a plurality of regions. In the first embodiment, the source diffusion layer 13 forms a conductive layer of the present invention. Each of the silicon oxidation films 12a to 12c forms a first insulation layer of the present invention. Each of the gate insulation films 10a to 10c forms a second insulation layer of the present invention.

Referring to FIG. 2, a planar conductor layer 15 is formed on the body diffusion layer 14, the source diffusion layer 13, and the silicon oxidation films 12a to 12c. The conductor layer 15 is formed from polysilicon containing a large amount of n-type impurity, such as phosphorous. The conductor layer 15 is directly connected to the source diffusion layer 13. In the first embodiment, the body diffusion layer 14 forms a diffusion layer of the present invention. The conductor layer 15 forms a conductor layer of the present invention.

Referring to FIG. 2, a silicon oxidation film 16 is formed on the conductor layer 15 and the epitaxial silicon layer 5. An insulation layer 20 is formed on the silicon oxidation film 16. Contact holes 21a and 21b are formed in the silicon oxidation film 16 and the insulation layer 20 at predetermined positions corresponding to the conductor layer 15 and the lead layers 19. A contact plug 22a is formed in each contact hole 21a. A contact plug 22b is formed in each contact hole 21b. A source electrode 23a, which is connected to each contact plug 22a, and a drain electrode 23b, which is connected to each contact plug 22b, are formed on the insulation layer 20. The source electrode 23a is formed so as to connect all of the source diffusion layers 13 defined by the gate electrodes 11a to 11c. In the first embodiment, the insulation layer 20 forms a third insulation layer of the present invention. The contact hole 21a forms a connection hole of the present invention. The source electrode 23a forms an electrode layer of the present invention.

The method for manufacturing the semiconductor device of the first embodiment will now be described.

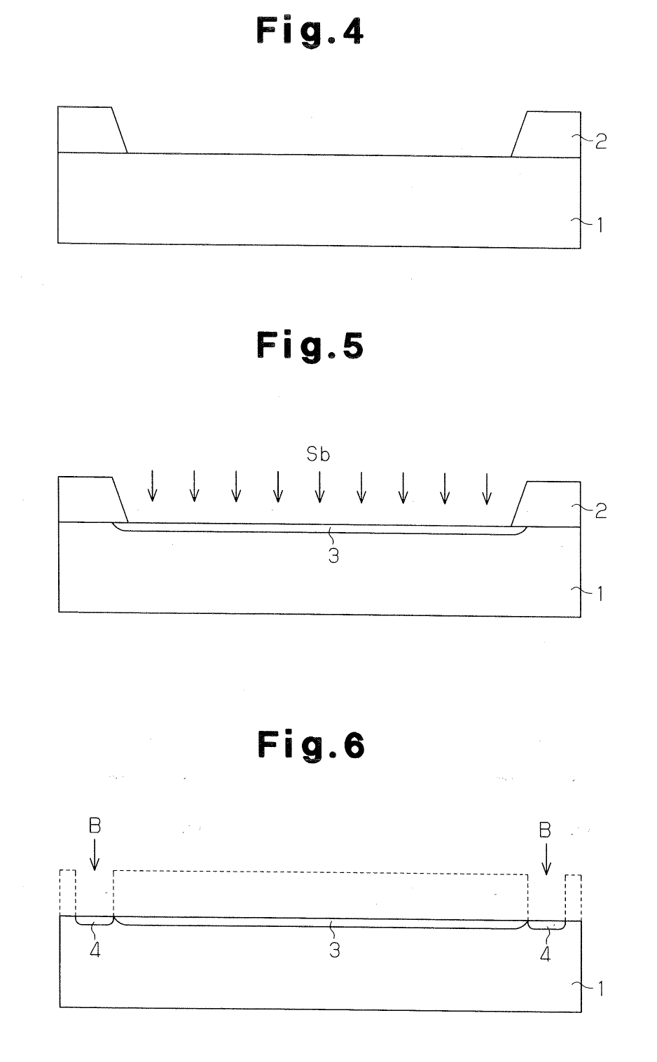

FIGS. 4 to 21 are schematic cross-sectional views showing processes for manufacturing the semiconductor device of FIG. 2.

Referring to FIG. 4, a thermal oxidation film 2 is first formed on the upper surface of a silicon substrate 1, and a predetermined region of the thermal oxidation film 2 is removed.

Referring to FIG. 5, an antimony (Sb) source is applied in the direction indicated by the arrows to the region from which the thermal oxidation film 2 has been removed by performed spin coating. The silicon substrate 1 is then subjected to heat treatment to form a buried diffusion layer 3.

Referring to FIG. 6, the thermal oxidation film 2 is removed. Then, a mask covering the upper surface of the buried diffusion layer 3 is formed as indicated by the broken lines in FIG. 6. Boron (B) is ion-implanted into the upper surface of the silicon substrate 1 in the direction indicated by arrows. The boron is then activated through a heat treatment. This forms an isolation diffusion layer 4 surrounding the buried diffusion layer 3.

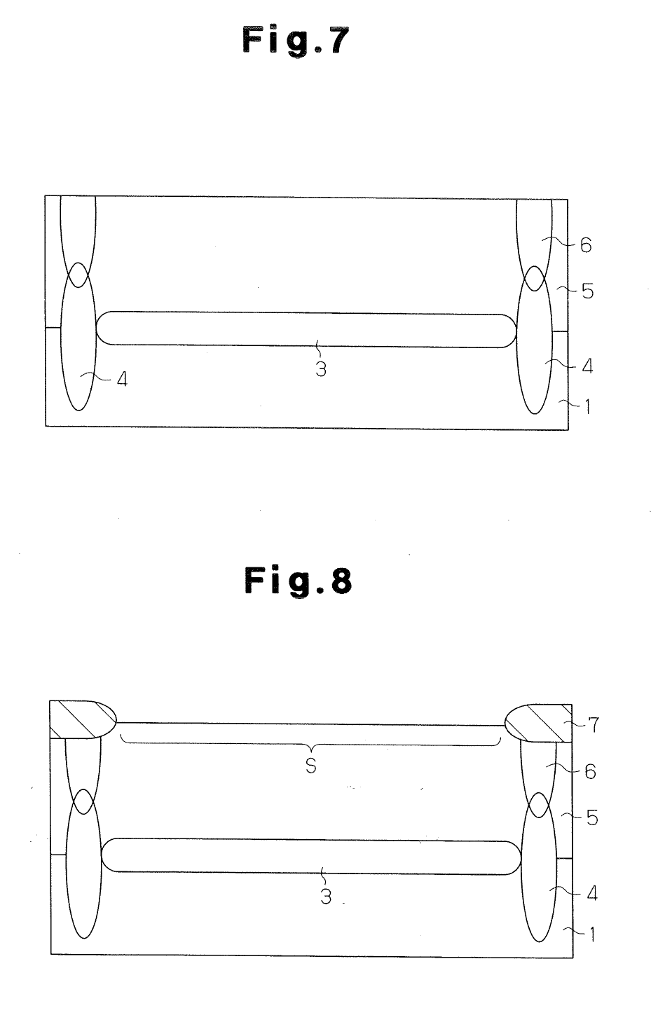

Referring to FIG. 7, an epitaxial silicon layer 5 is formed on the buried diffusion layer 3. A resist mask (not shown) is formed on the epitaxial silicon layer 5, and boron is ion-implanted into the upper surface of the epitaxial silicon layer 5. The boron is then activated through a heat treatment. This forms an isolation diffusion layer 6 that reaches the isolation diffusion layer 4.

Referring to FIG. 8, a LOCOS layer 7, which has the shape of a rectangular frame, is formed on the isolation diffusion layer 6 (refer to FIG. 3). As a result, an isolation layer formed by the LOCOS layer 7 and the isolation diffusion layers 4 and 6 define a semiconductor element formation region S.

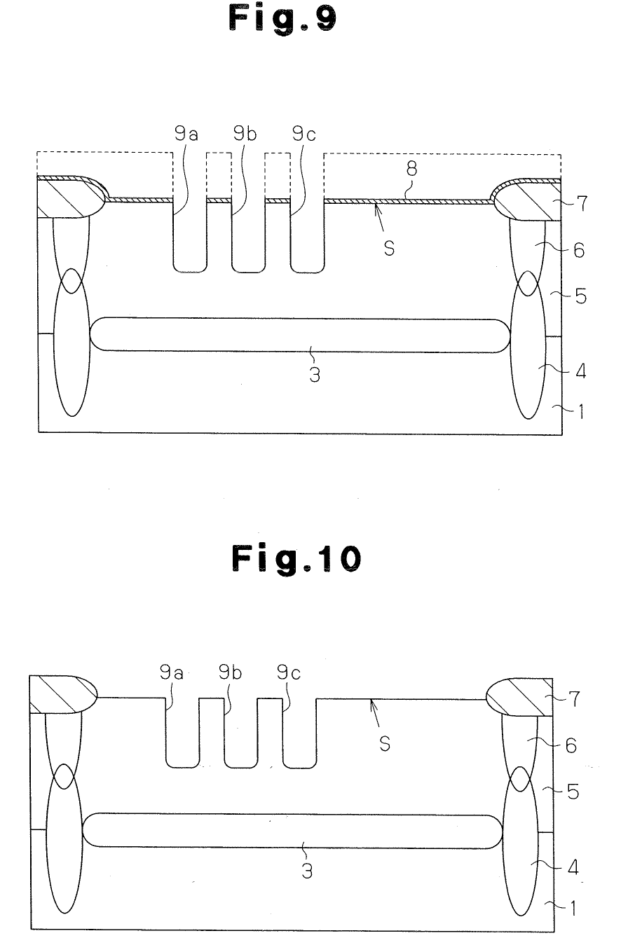

Referring to FIG. 9, a silicon nitride film 8 is formed, and a resist mask for forming trenches 9a to 9c (indicated by broken lines) is formed on the silicon nitride film 8. The silicon nitride film 8 and the epitaxial silicon layer 5 are etched and sequentially removed to form the trenches 9a to 9c. Referring to FIG. 2, the trenches 9a to 9c are arranged in parallel at regular intervals in the formation region S. Further, as shown in FIG. 2, the trenches 9a to 9c are formed to be deep enough to extend through both of the source diffusion layer 13 and body diffusion layer 14, which are formed in subsequent processes, but not deep enough to extend to the buried diffusion layer 3. The resist mask and the silicon nitride film 8 are then removed as shown in FIG. 10.

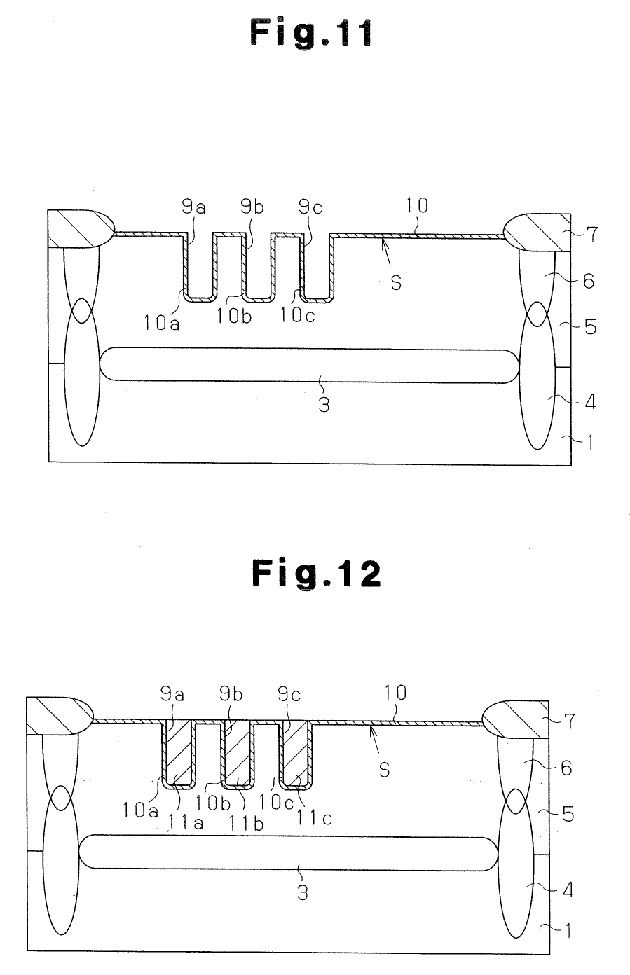

Referring to FIG. 11, the inner surfaces of the trenches 9a to 9c and the upper surface of the epitaxial silicon layer 5 are subjected to heat treatment. This forms a silicon oxidation film 10 (functioning as gate insulation films 10a to 10c in the trenches 9a to 9c).

Referring to FIG. 12, polysilicon is deposited in the trenches 9a to 9c and on the epitaxial silicon layer 5. The polysilicon is then doped with phosphorous (P). Afterwards, the polysilicon is etched to form gate electrodes 11a to 11c in the trenches 9a to 9c.

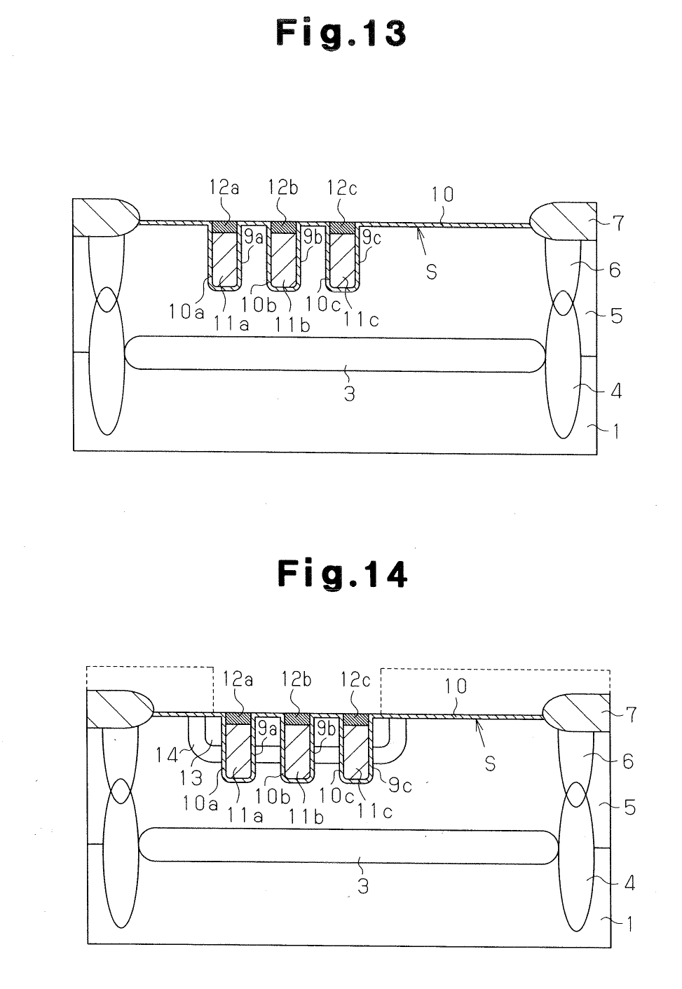

Referring to FIG. 13, portions of the gate electrodes 11a to 11c formed from polysilicon are thermally oxidized in a self-aligned manner. This forms silicon oxidation films 12a to 12c on the surfaces of the gate electrodes 11a to 11c. The surfaces of the gate electrodes 11a to 11c are oxidized after the gate electrodes 11a to 11c are filled in the trenches 9a to 9c. Thus, the silicon oxidation films 12a to 12c are formed to extend in parallel at regular intervals along the trenches 9a to 9c.

Referring to FIG. 14, a resist mask (indicated by broken lines) having an opening corresponding to a source formation region is formed. Arsenic (As) is ion-implanted into the upper surface of the epitaxial silicon layer 5. Boron is ion-implanted at a position deeper than the position at which the arsenic has been implanted. The resist mask is then removed. The arsenic and boron are activated through a heat treatment. This forms a source diffusion layer 13 and a body diffusion layer 14 in the epitaxial silicon layer 5. The silicon oxidation film 10 functions to protect the surface of the epitaxial silicon layer 5 when the ions are implanted.

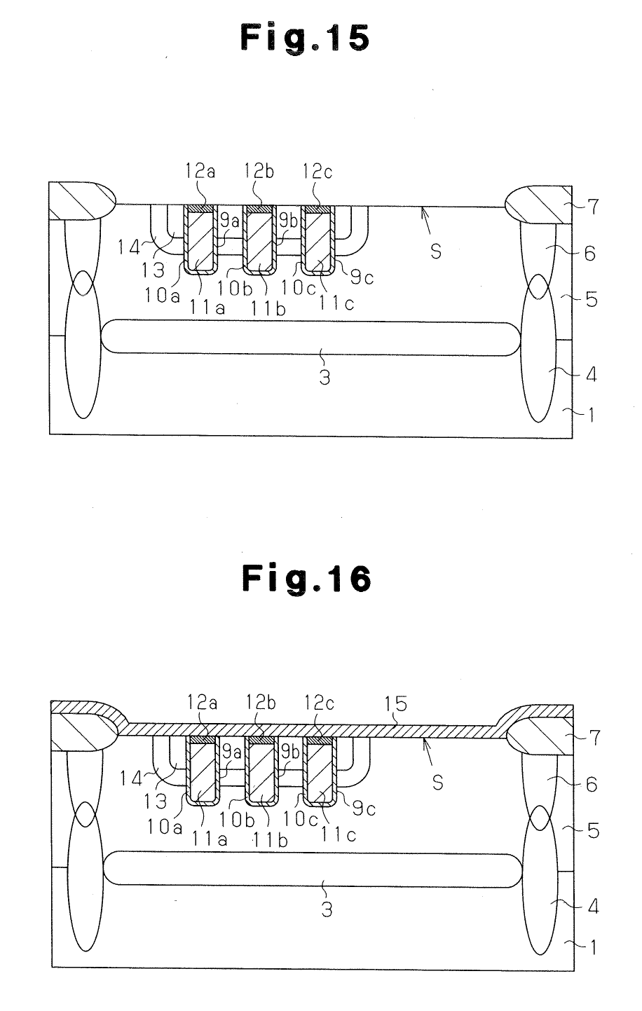

Referring to FIG. 15, the silicon oxidation film 10 is removed from the epitaxial silicon layer 5. At the same time, surface portions of the silicon oxidation films 12a to 12c are also removed. As a result, the upper surfaces of the silicon oxidation films 12a to 12c become substantially flush with the upper surface of the source diffusion layer 13.

Referring to FIG. 16, polysilicon for forming a conductor layer 15 is applied to the epitaxial silicon layer 5, and the polysilicon is doped with phosphorous.

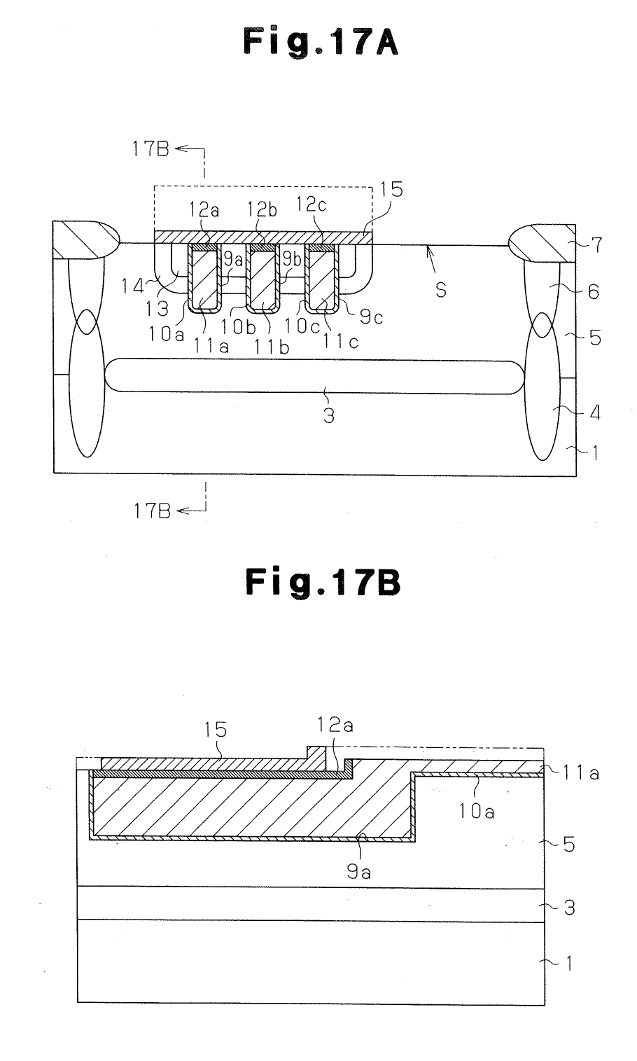

Referring to FIG. 17A, a resist mask (indicated by broken lines) having an opening corresponding to regions other than a formation region for the conductor layer 15 is formed, and the conductor layer 15 is etched. The resist mask is then removed. This forms the planar conductor layer 15 on the body diffusion layer 14, the source diffusion layer 13, and the silicon oxidation films 12a to 12c. As described above, the upper surfaces of the silicon oxidation films 12a to 12c are substantially flush with the upper surface of the source diffusion layer 13. Thus, the upper surface of the conductor layer 15 is flat. This reduces manufacturing variations between source electrodes 23a, which will be formed in subsequent processes, and improves the reliability of the connection between the source electrodes 23a and the conductor layer 15.

The conductor layer 15 is arranged to cover the source diffusion layer 13 and the body diffusion layer 14. However, the conductor layer 15 is not arranged on the epitaxial silicon layer 5. This prevents short-circuiting of the source diffusion layer 13 and the epitaxial silicon layer 5 via the conductor layer 15. When the conductor layer 15 has a larger area, the area of connection between the source electrodes 23a and contact plugs 22a, which will be formed in subsequent processes, increases. The increased connection area between the source electrodes 23a and the contact plugs 22a reduces the connection resistance of the source electrodes 23a. Accordingly, the conductor layer 15 preferably has substantially the same area as the body diffusion layer 14.

FIG. 17B is a cross-sectional view taken along line 17B-17B in FIG. 17A. The conductor layer 15 is processed by etching a region indicated by the double-dashed lines in FIG. 17B. The conductor layer 15 is not arranged on the epitaxial silicon layer 5 and the gate electrode 11a. This structure prevents short-circuiting between the source diffusion layer 13 and the epitaxial silicon layer 5 via the conductor layer 15 and between the gate electrode 11a and the source diffusion layer 13 via the conductor layer 15. In the example shown in FIG. 17B, the gate electrode 11a is exposed from above the epitaxial silicon layer 5 at one end (right end as viewed in the drawing) of the trench 9a to enable wiring. However, the gate electrode 11a may be exposed from the epitaxial silicon layer 5 at the two ends of the trench 9a.

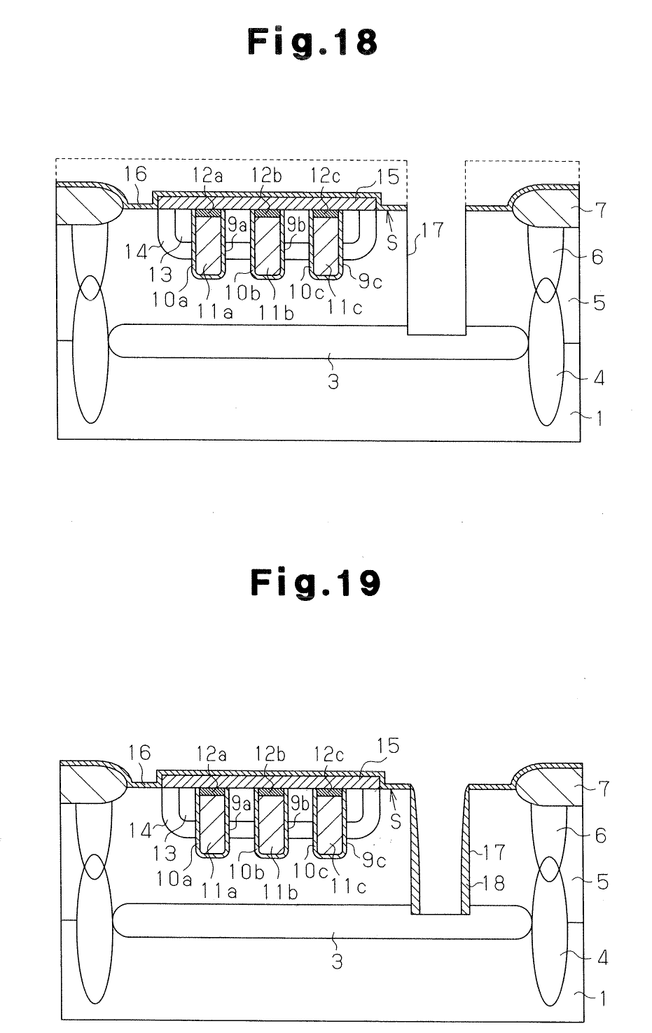

Referring to FIG. 18, the silicon oxidation film 16 is formed on the epitaxial silicon layer 5 including the conductor layer 15. A resist mask (indicated by the broken lines in FIG. 18) for forming trenches 17 is formed on the silicon oxidation film 16. The silicon oxidation film 16 and the epitaxial silicon layer 5 are etched and sequentially removed to form the trenches 17. The resist mask is then removed. The trenches 17 are formed in the formation region S in a manner that one trench corresponds to a predetermined number of gate electrodes. The trenches 17 are deep enough to reach the buried diffusion layer 3.

Referring to FIG. 19, a silicon oxidation film is deposited on the silicon oxidation film 16 and in the trenches 17. The entire surface of the deposited silicon oxidation film is then etched back. This forms a silicon oxidation film 18 functioning as a spacer on the inner surface of each trench 17. More specifically, the inner surface of each trench 17 is covered by the silicon oxidation film 18. A portion of the silicon oxidation film is removed from the bottom of each trench 17. The silicon oxidation film 18 prevents the diffusion of impurities contained in polysilicon forming the lead layer 19 (refer to FIG. 2), which will be formed in subsequent processes, and ensures the required withstand voltage with the surrounding epitaxial silicon layer 5.

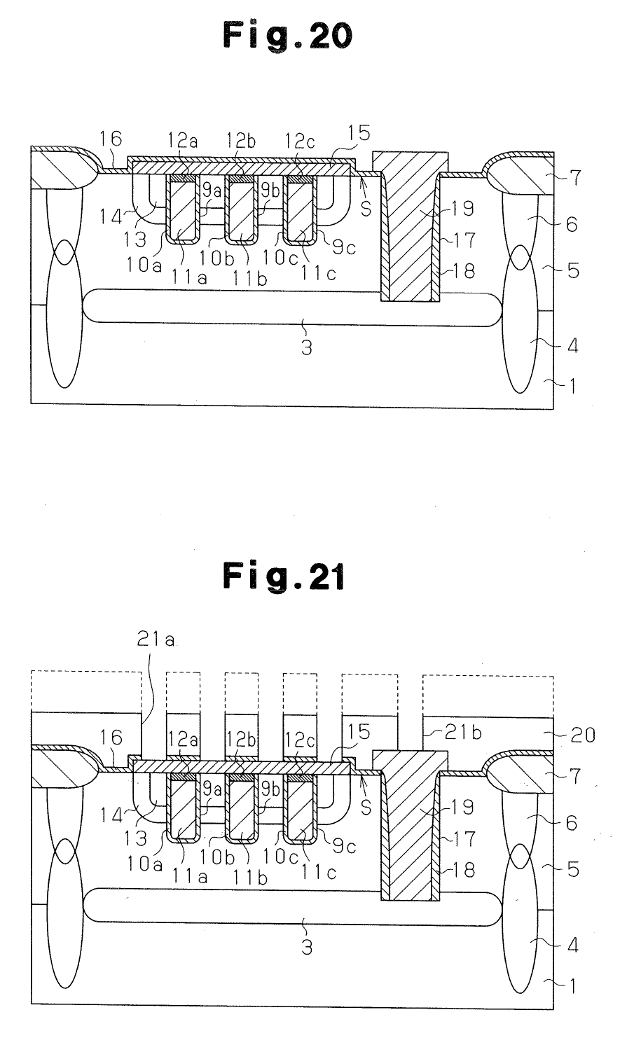

Referring to FIG. 20, polysilicon is deposited in the trenches 17 and on the epitaxial silicon layer 5. The polysilicon is then doped with phosphorous. Afterwards, the polysilicon is etched to form the lead layer 19 in each trench 17. The lead layer 19 is electrically connected to the buried diffusion layer 3 via the bottom of each trench 17.

Referring to FIG. 21, an insulation layer 20 is formed on the entire surface of the epitaxial silicon layer 5. Afterwards, a resist mask for forming contact holes 21a and 21b is formed in a predetermined region of the conductor layer 15 and the lead layer 19 as indicated by the broken lines. In this case, even if the resist mask is misaligned, the conductor layer 15, which is planar, absorbs the influence of such misalignment. The insulation layer 20 and the silicon oxidation film 16 are etched and sequentially removed to form the contact holes 21a and 21b. Then, the resist mask is removed.

Finally, tungsten (W) is deposited in the contact holes 21a and 21b as shown in FIG. 2. The tungsten is etched back to form contact plugs 22a and 22b in the contact holes 21a and 21b, respectively. Metal wires forming source electrodes 23a are formed on the contact plugs 22a, and metal wires forming drain electrodes 23b are formed on the contact plugs 22b.

The semiconductor device of the first embodiment has the advantages described below.

(1) The source electrodes 23a and the source diffusion layers 13 are connected via the conductor layer 15 arranged between the source electrodes 23a and the source diffusion layers 13. This eliminates the problem of misalignment between the source region 45 and the contact holes 49a even when narrowing the source diffusion layers 13 (i.e., arranging the trenches 9a to 9c are arranged at finer intervals). Thus, the size of the semiconductor device can be reduced.

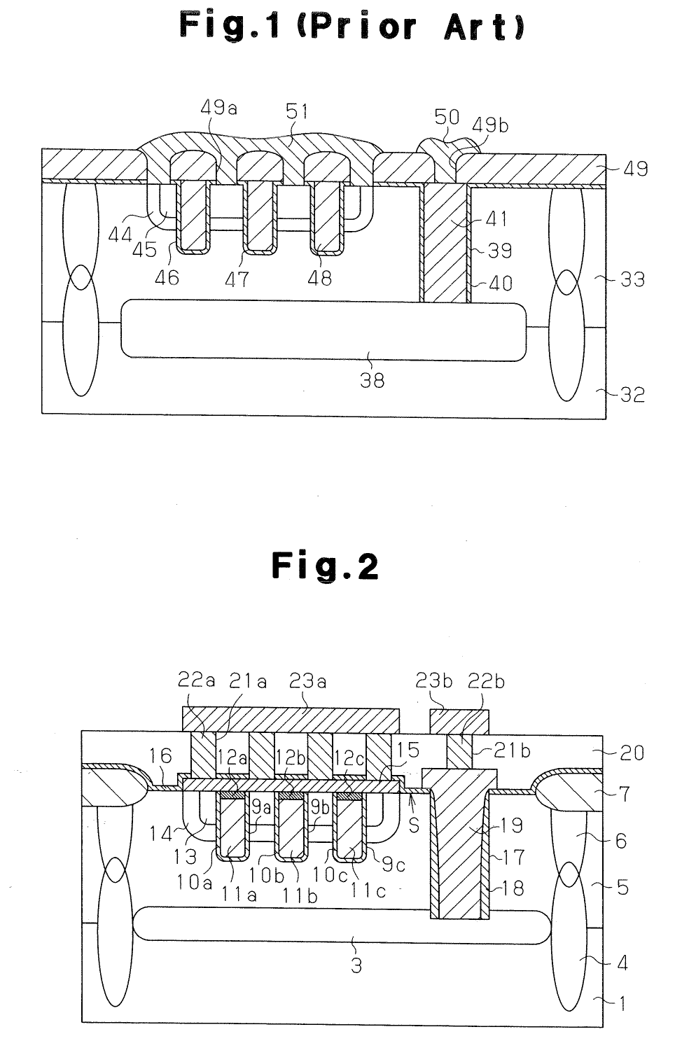

Further, the area of connection between the source electrodes 23a and the contact plugs 22a is increased. With the conventional technique (FIG. 1), the area of connection between the source region 45 and the source electrodes 51 via the contact holes 49a is limited by the dimensions of the source regions 45 (dimensions of the contact holes 49a). In contrast, the semiconductor device of the first embodiment includes the conductor layer 15, which is planar, on the source diffusion layers 13. Thus, the number of the contact holes 21a and the dimensions of the contact holes 21a may be determined without having to consider the dimensions of the source diffusion layers 13. As a result, the connection resistance between the source electrodes 23a and the conductor layer 15 is reduced.

(2) The conductor layer 15 may be arranged to cover the body diffusion layer 14. In this case, the contact holes 21a may be arranged in a region other than the region in which the source diffusion layer 13 is formed. This improves the design freedom of the semiconductor device.

(3) In the first embodiment, the conductor layer 15 is formed from polysilicon, and the body diffusion layer 14 and the source diffusion layer 13 are formed using the epitaxial silicon layer 5. This enables the conductor layer 15 to reduce the connection resistance of the source electrodes 23a while maintaining the characteristics of the semiconductor element in a preferable manner.

### Second Embodiment

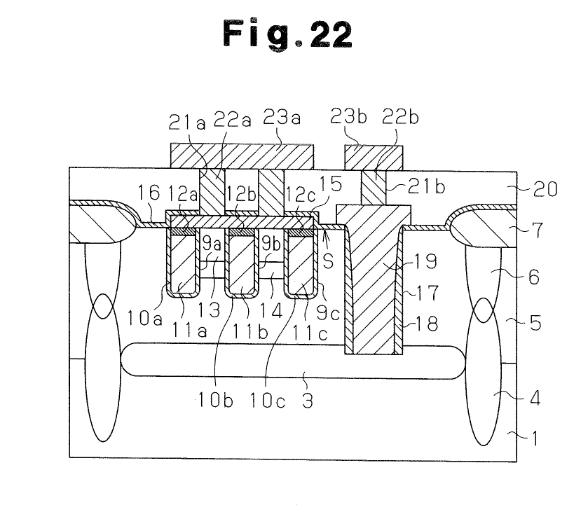

FIG. 22 shows a semiconductor device according to a second embodiment of the present invention. In FIG. 22, the source diffusion layer 13 and body diffusion layer 14 are formed only between the gate electrodes 11a and 11b and between the gate electrodes 11b and 11c. In this case, the conductor layer 15 is formed on the source diffusion layer 13 and the silicon oxidation films 12a to 12c but not on the epitaxial silicon layer 5. This embodiment also has advantage (1) of the first embodiment.

It should be apparent to those skilled in the art that the present invention may be embodied in many other specific forms without departing from the spirit or scope of the invention. Particularly, it should be understood that the present invention may be embodied in the following forms.

The conductor layer of the present invention may be formed by a metal layer instead of a polysilicon layer. In this case, titanium, tungsten, cobalt, tantalum, platinum, nickel, molybdenum, or a silicide of these elements may be used as the metal material of the metal layer forming the conductive layer. Metal has a smaller heat capacity than polysilicon. Thus, the conductor layer 15 can be formed at a much lower temperature than when-using polysilicon. Accordingly, when the conductor layer 15 is formed from a metal material, the formation of the source diffusion layer 13 and the body diffusion layer 14 is less likely to be affected by the heat generated when forming the conductor layer 15. Further, the conductor layer 15 formed using the metal material has a higher etching selectivity than the epitaxial silicon layer 5 when the conductor layer 15 is etched. This reduces the damages inflicted on the epitaxial silicon layer 5 when the conductor layer 15 is etched.

In the first and second embodiments (FIGS. 2 and 22), the contact holes 21a are arranged between and adjacent to the gate electrodes. However, the contact holes 21a may be arranged on or at the interfaces of the gate electrodes. Further, the contact holes 21a may be arranged in a zigzagged manner. Alternatively, the contact holes 21a may be formed to be larger than the source diffusion layers 13. Such structures obtain advantages (1) and (2), which are described above.

In the first embodiment (FIG. 17A), the conductor layer 15 is formed in correspondence with the body diffusion layer 14. However, for example, the conductor layer 15 may be formed in correspondence with the source diffusion layer 13. Such a structure obtains advantage (1), which is described above.

In the first embodiment (FIG. 17A), the upper surfaces of the silicon oxidation films 12a to 12c are formed to be substantially flush with the upper surface of the source diffusion layer 13. However, the upper surfaces of the silicon oxidation films 12a to 12c may be formed at a level higher than the upper surface of the source diffusion layer 13 or at a level lower than the upper surface of the source diffusion layer 13. Accordingly, the upper surfaces of the silicon oxidation films 12a to 12c may be protruded or recessed surfaces. Such structures also obtain advantages (1) and (2), which are described above. Further, the conductor layer may be divided on the gate electrodes (the silicon oxidation films 12a to 12c) so as to form a plurality of conductor layers. In this case, contacts are formed in an optimum manner as long as the surface area of the conductor layers is greater than the surface area of the source diffusion layers 13.

The present examples and embodiments are to be considered as illustrative and not restrictive, and the invention is not to be limited to the details given herein, but may be modified within the scope and equivalence of the appended claims.

What is claimed is:

1. A semiconductor device comprising:
a semiconductor substrate having a surface;
a plurality of gate electrodes buried in the semiconductor substrate;
a plurality of first insulation layers respectively arranged on the plurality of gate electrodes;
a conductive layer formed on the surface of the semiconductor substrate near the plurality of gate electrodes and the plurality of first insulation layers; and
a conductor layer arranged on at least the conductive layer.

2. The semiconductor device according to claim 1, further comprising:
a plurality of second insulation layers arranged between at least the conductive layer and the plurality of gate electrodes;
wherein the conductor layer is formed on the conductive layer and the plurality of first insulation layers.

3. The semiconductor device according to claim 1, further comprising:
a diffusion layer formed on the semiconductor substrate adjacent to the conductive layer;
wherein the conductor layer is arranged on the conductive layer and the diffusion layer.

4. The semiconductor device according to claim 3, wherein the plurality of first insulation layers, the conductive layer, and the diffusion layer each has an upper surface, with the upper surfaces of the plurality of first insulation layers, the upper surface of the conductive layer, and the upper surface of the diffusion layer being substantially flush with one another.

5. The semiconductor device according to claim 1, wherein:
the semiconductor substrate is a silicon substrate; and
the conductor layer is formed from polysilicon.

6. The semiconductor device according to claim 1, wherein:
the semiconductor substrate is a silicon substrate; and
the conductor layer is formed from a metal material.

7. The semiconductor device according to claim 1, wherein the conductive layer is planar.

8. The semiconductor device according to claim 1, further comprising:
a third insulation layer formed above the conductor layer and having connection holes; and
an electrode layer formed on the third insulation layer and connected to the conductor layer via the connection holes.

9. A method for manufacturing a semiconductor device, the method comprising:
preparing a semiconductor substrate having a surface;
burying a plurality of gate electrodes in the semiconductor substrate;
arranging a plurality of first insulation layers respectively on the plurality of gate electrodes;
forming a conductive layer on the surface of the semiconductor substrate near the plurality of gate electrodes and the plurality of first insulation layers; and
arranging a conductor layer on at least the conductive layer.

10. The method according to claim 9, further comprising:
arranging a plurality of second insulation layers between at least the conductive layer and the plurality of gate electrodes;
wherein said arranging a conductor layer includes arranging the conductor layer on the conductive layer and the plurality of first insulation layers.

11. The method according to claim 9, further comprising:
forming a diffusion layer on the semiconductor substrate adjacent to the conductive layer;
wherein said arranging a conductor layer includes arranging the conductor layer on the conductive layer and the diffusion layer.

12. The method according to claim 9, further comprising:
arranging a third insulation layer on the conductor layer;
forming connection holes in the third insulation layer; and
arranging an electrode layer on the third insulation layer, wherein the electrode layer is connected to the conductor layer via the connection holes.
